(19) United States
(12) Patent Application Publication
(10) Pub. No.: US 2010/0296211 A1
(43) Pub. Date: Nov. 25, 2010

(54) COMPACT APPARATUS

(75) Inventor: Olivier Bruandet, Tottijarvi (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/520,264

(22) PCT Filed: Dec. 21, 2006
(86) PCT No.: PCT/IB06/04171

§ 371 Date: Jul. 27, 2010

(51) Int. Cl. H02H 9/04; H05K 7/02

(52) U.S. Cl. 361/56; 361/760

(57) ABSTRACT

An apparatus comprising: a first component that is electrically conductive but electrically isolated; a ground point; and an intermediate component positioned adjacent the first component and adjacent the ground point comprising an electrically conductive portion for electrically connecting the first component and the ground point.

### FIELD OF THE INVENTION

Some embodiments of the present invention relate to a compact apparatus. In particular, some embodiments of the invention relate to the close packing of components while mitigating undesirable consequences arising from such close packing.

### BACKGROUND TO THE INVENTION

It is often desirable to create electronic apparatus with a small size. There is currently much on-going research into how to create more compact processors, memories, batteries etc.

Given components of a certain size there may be a range of different configurations in which the components can be relatively arranged within a housing. The optimal configuration is unlikely to simply be the configuration that is optimal for the physical dimensions of the components because the close positioning of certain components may result in undesirable consequences such as interference, physical damage or electro-static discharge damage. However, if the positioning of components is constrained because of the potential undesirable consequences of their interaction it may be difficult or impossible to produce a compact housing.

It would be desirable to mitigate the undesirable consequences that could arise when components are placed in close proximity.

### BRIEF DESCRIPTION OF THE INVENTION

According to some embodiments of the invention there is provided an apparatus comprising: a first component that is electrically conductive but electrically isolated; a ground point; and an intermediate component positioned adjacent the first component and adjacent the ground point comprising an electrically conductive portion for electrically connecting the first component and the ground point.

These embodiments mitigate the undesirable consequences that could arise when the first component, the ground point and intermediate functional component are placed in close proximity. The solution provides a controlled electro-static discharge path to ground from the first component in an elegant manner using an electrically conductive portion comprised in the intermediate functional component.

According to some embodiments of the invention there is provided a method comprising: arranging an intermediate component that is positioned adjacent a first component to perform a first function, to additionally provide an element that provides for electro-static discharge between the first component and a ground point.

According to some embodiments of the invention there is provided a component for positioning adjacent a first component of an electronic apparatus to perform a first function and comprising, for the performance of an additional electro-static discharge function, an electro-static discharge element that is arranged to provide an electric discharge path from the first component.

### BRIEF DESCRIPTION OF THE DRAWINGS

For a better understanding of the present invention reference will now be made by way of example only to the accompanying drawings in which:

FIG. 1 schematically illustrates an apparatus;

FIG. 2a is a schematic cross-section of an apparatus according to a particular embodiment; and

FIG. 2b is an elevated perspective view of the apparatus illustrated in cross-section in FIG. 2a.

### DETAILED DESCRIPTION OF EMBODIMENTS OF THE INVENTION

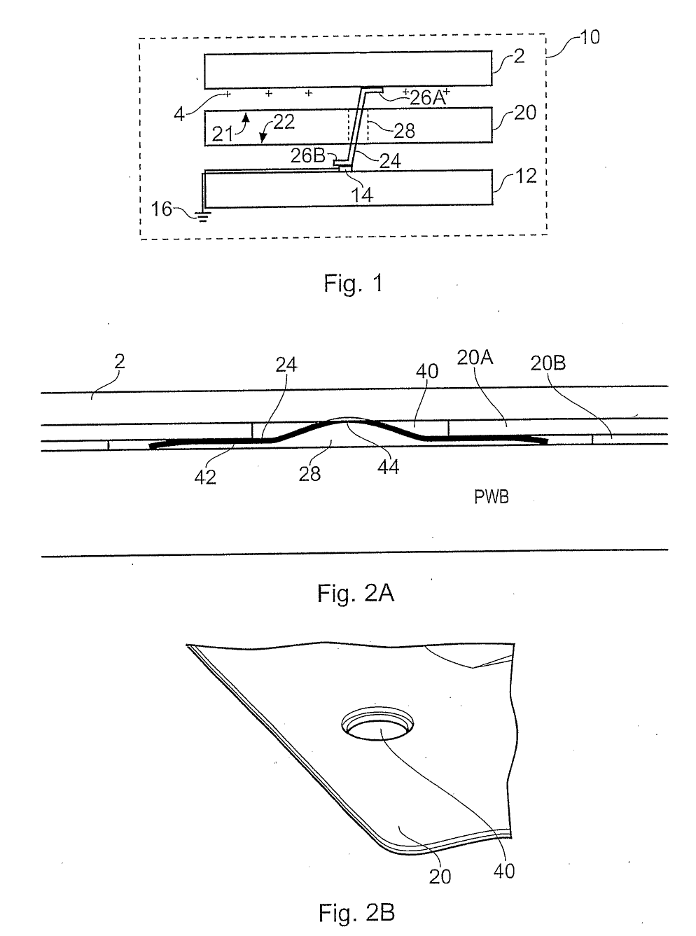

FIG. 1 schematically illustrates an apparatus 10. The apparatus 10 comprises a first component 2, a ground point 14 and an intermediate component 20 adjacent the first component 2 and adjacent the ground point 14.

The intermediate component 20 is positioned so that it underlies the first component 2 and overlies the ground point 14. A first upper surface 21 of the intermediate component 20 is adjacent the first component 2 and a second lower surface 22 of the intermediate component 20 is adjacent the ground point 14.

The first component 2 may comprise material that it is electrically isolated. That is there is no DC connection between the first component 2 and ground 16 other than as described below. The absence of a dc current discharge path to ground from the first component 2 results in it being susceptible to storing electrostatic charge 4. As is known in the art, this electrostatic charge may build to the point where it discharges suddenly through surrounding insulating/dielectric material, such as air, to ground. Such an electrostatic discharge creates very high voltages which may damage intermediate component 20 that is in the discharge path between the first component 2 and ground 16.

The intermediate component 20 comprises an electrically conductive portion 24 that operates as an electrostatic discharge element. This electrostatic discharge element provides a galvanic (DC) current path from the first component 2, via the body of the intermediate component 20, to ground 16 via the ground point 14. The electrostatic discharge element may be metallic.

The intermediate component 20 is ‘functional’ in that it provides a function other than housing the electrostatic discharge element 24. It may, for example, have connected electrical components 30 that control the performance of this function. As an example, the intermediate component 20 may be a layer of electroluminescent (EL) material and the electrical components 30 may be current drivers for providing electrical energy to the electroluminescent material and causing it to emit light.

The electrostatic discharge element 24 enables the intermediate component 20 to provide an additional function, namely an electrostatic discharge path from the first component 2 to the ground point 14. The electrostatic discharge path prevents the build up of electrostatic charge 4 on the first component 2. As a consequence, the path of least resistance to ground 16 for electrostatic charge on the first component is via the low resistance electrostatic discharge element 24. The preferred discharge route to ground from the first component 2 through the intermediate component 20 to ground 16 is via the electrostatic discharge element and not via the body of the intermediate component 20.

This protects the electronic components 30 from the high voltages created by a discharge through the body of the intermediate component 20.

The ground point 14 is typically a pad provided on an upper surface of a printed wiring board (PWB) 12 and it is electrically connected to ground 16.

The electrostatic discharge element 24 has one or more resiliently deformable portions 26A, 26B that provide for sprung contact between the electrostatic discharge element 24 and the first component 2 and/or between the electrostatic element 24 and the ground point 14. The electrostatic discharge element 24 may, for example, be formed by a shaped piece of metal that travels through an aperture 28 that extends through the intermediate component 20 from the lower surface 22 to the upper surface 21. The shaped piece of metal may be covered in electrically insulating material for the portion within the body of the intermediate component 20.

In one embodiment, the aperture 28 may be over sized so that the electrostatic discharge element is comfortably housed within it but is a distinct element, separate from but comprised in the intermediate component 20. In another embodiment, the aperture 28 may be such that the electrostatic discharge element 24 that is held by friction such that the electrostatic discharge element 24 is an integral part of the intermediate component 20.

The electrostatic discharge element 24 enables the first component 2, the intermediate component 20 and the PWB 12 to be placed in close proximity without the risk of damage to the intermediate component 20 by electrostatic discharge from the first component 2 to the grounded PWB 12 through the body of the intermediate component 20.

FIGS. 2a and 2b schematically illustrate one embodiment of the apparatus 10 in which the first component 2 is electrically conductive. FIG. 2a is a schematic cross-section and FIG. 2b is from a view from an elevated perspective. The first component 2 is a supporting element, a metallic frame for a keypad of a hand portable electronic device, such as a mobile cellular telephone. It should be appreciated that in other implementations, the first component 2 may be a different physical feature of the device such as a decorative strip, electromagnetic shielding, a battery cover etc.

The intermediate component 20 is, for example, an electroluminescent layer that is used to illuminate the keypad or a PET sheet. The ground point 14 is a pad on a PWB 12 of the apparatus.

The electrostatic discharge element 24, in this example, is a metal dome 40. The dome 40 is one-piece having a base portion 42 and a vaulted portion 44. The vaulted portion 44 provides raised relief. It has a shape that approximates to a section of a sphere or ellipsoid. The base portion 42 resembles an annulus and is used to support the vaulted portion 44. The base portion in this example is bent downwards at its edges to provide a sprung contact 26B. The apex of the vaulted portion 44 of the dome 40 provides a sprung contact 26A. The dome 40 therefore provides a resiliently deformable electrical contact between the ground point 14 and the first component 2. The resilient deformation may arise from deformation of the vaulted portion 44 itself and/or from deformation of the base portion 42.

The height (h) of the dome is such that, in use, the first component 2 contacts the dome 40 which is resiliently deformed. Thus a reliable electrical contact is formed between the first component 2 and the electrostatic discharge element 20.

The height h is generally small, of the order of a few tenths of mm. This enables the first component 2, intermediate component 20 and PWB 12 to be positioned in close proximity without undesirable consequences such as electro-static discharge damage to the intermediate component 20. This enables the apparatus 10 to have a lower height profile.

Although the electrically conductive portion 24 of the intermediate component 20 has been described above as operating as an electrostatic discharge element it may, in other implementations operate in a different manner. The electrically conductive portion 24 of the intermediate component 20 may be used to ground a ‘floating’ first component that would otherwise disturb the performance of a cellular antenna of the apparatus 10.

Although embodiments of the present invention have been described in the preceding paragraphs with reference to various examples, it should be appreciated that modifications to the examples given can be made without departing from the scope of the invention as claimed.

Whilst endeavoring in the foregoing specification to draw attention to those features of the invention believed to be of particular importance it should be understood that the Applicant claims protection in respect of any patentable feature or combination of features hereinbefore referred to and/or shown in the drawings whether or not particular emphasis has been placed thereon.

I/We claim:

1. An apparatus comprising:
a first component that is electrically conductive and electrically isolated;
a ground point; and
an intermediate component positioned adjacent the first component and adjacent the ground point comprising an electrically conductive portion arranged to electrically connect the first component and the ground point.

2. An apparatus as claimed in claim 1, wherein the intermediate component performs a first function in addition to a grounding function performed by the electrically conductive portion.

3-18. (canceled)

19. An apparatus as claimed in claim 1, wherein the intermediate component is connected to one of electronic and electromechanical components.

20. An apparatus as claimed in claim 1, wherein the intermediate component is a layer of material.

21. An apparatus as claimed in claim 1, wherein the intermediate component is an electro-luminescent layer.

22. An apparatus as claimed in claim 1, wherein the intermediate component is positioned between the first component and the ground point.

23. An apparatus as claimed in claim 1, wherein the conductive portion is resiliently deformable.

24. An apparatus as claimed in claim 1, wherein the intermediate conductive portion is sprung.

25. An apparatus as claimed in claim 1, wherein the intermediate conductive portion is a dome

26. An apparatus as claimed in claim 1, wherein the intermediate conductive portion is metallic.

27. An apparatus as claimed in claim 1, wherein the intermediate component has a through aperture for the conductive portion.

28. An apparatus as claimed in claim 1, wherein the intermediate conductive portion is included within the intermediate component as an integral part thereof.

29. An apparatus as claimed in claim 1, wherein the first component is metallic.

30. An apparatus as claimed in claim 1, wherein the first component is part of a keypad.

31. An apparatus as claimed in claim 1, wherein the ground point is part of printed wired board.

32. An apparatus as claimed in claim 1 operable as one of a hand-portable electronic device and module for a hand portable electronic device

33. A method comprising:
arranging an intermediate component that is positioned adjacent a first component to perform a first function, to additionally provide an element that provides for electro-static discharge between the first component and a ground point.

34. A component for positioning adjacent a first component of an electronic apparatus to perform a first function and comprising, for the performance of an additional electro-static discharge function, an electro-static discharge element that is arranged to provide an electric discharge path from the first component.
